(19) United States
(12) Patent Application Publication
(10) Pub. No.: US 2019/0139928 A1
(43) Pub. Date: May 9, 2019

(54) DIE BONDING RESIN LAYER FORMING APPARATUS

(71) Applicant: DISCO CORPORATION, Tokyo (JP)

(72) Inventor: Kazuma SEKIYA, Tokyo (JP)

(21) Appl. No.: 16/181,840

(22) Filed: Nov. 6, 2018

(30) Foreign Application Priority Data
Nov. 8, 2017 (JP) 2017-215843

(51) Int. Cl. H01L 23/00

(52) U.S. Cl. CPC H01L 24/75; H01L 24/27; H01L 24/29; H01L 2224/27418; H01L 2224/7598; H01L 2224/2919; H01L 2224/75651; H01L 2224/75744; H01L 2224/27515

(57) ABSTRACT

A die bonding resin layer forming apparatus includes a liquid resin applying part including a chuck table that holds a wafer in such a manner that the back surface side is exposed and an applying unit that applies a liquid resin to the back surface side of the wafer held by the chuck table, a waiting part that holds the wafer to which the liquid resin has been applied by the liquid resin applying part and waits to dry the liquid resin applied to the wafer while enhancing flatness of the liquid resin, a curing part that gives an external stimulus to the liquid resin dried by the waiting part to cure the liquid resin and form the die bonding resin layer, and a conveying unit that conveys the wafer among the liquid resin applying part, the waiting part, and the curing part.

### BACKGROUND OF THE INVENTION

### Field of the Invention

The present invention relates to a die bonding resin layer forming apparatus that forms a resin layer for die bonding on the back surface side of a wafer having plural devices on the front surface side.

### Description of the Related Art

A wafer on which plural devices are formed on the front surface side is subjected to cutting processing or laser processing along planned dividing lines (streets) for example to be divided into plural device chips corresponding to the respective devices. In order to stack this device chip on a substrate, another device chip, or the like and fix the device chip thereto, a thin-film-shaped adhesive called a die attach film (DAF) is often provided on the back surface side of the device chip.

For example, the die attach film is formed to a size with which the whole of a wafer can be covered, and is stuck to the back surface of the wafer before dividing. By sticking the die attach film to the back surface of the wafer and then dividing this die attach film with the wafer, device chips having an adhesive on the back surface side can be formed.

Incidentally, in the case of employing a processing method such as dicing first (dicing before grinding: DBG) in which the back surface side of a wafer is ground after grooves for dividing are formed on the front surface side, the die attach film can not be stuck to the back surface of the wafer before dividing. Thus, in this case, for example, the die attach film is stuck to the back surface of the wafer after the wafer is divided into plural device chips.

However, in this method, only the die attach film needs to be divided by laser processing or the like after the die attach film is stuck (for example, refer to Japanese Patent Laid-open No. 2014-220417). Thus, the cost relating to manufacturing of device chips readily becomes high. Against this problem, a method in which a liquid-state resin is sprayed onto the back surface of a wafer after being divided into device chips to form a resin layer functioning as an adhesive has been proposed (for example, refer to Japanese Patent Laid-open No. 2017-41574).

### SUMMARY OF THE INVENTION

However, in the above-described method in which a liquid-state resin is sprayed onto a wafer after dividing, the resin layer becomes thicker or thinner at the central part of the device chip than at the peripheral part and recess and projection are readily generated. For this reason, if the resin layer formed in this method is used as the adhesive, the possibility that the whole of the bonding surface of the device chip can not be properly bonded to a substrate or the like of the target becomes high.

Thus, an object of the present invention is to provide a die bonding resin layer forming apparatus that can form a resin layer for die bonding with high flatness on a wafer.

In accordance with an aspect of the present invention, there is provided a die bonding resin layer forming apparatus that forms a die bonding resin layer on a back surface side of a wafer on which devices are formed in a plurality of regions on a front surface side marked out by a plurality of planned dividing lines. A protective member is stuck to the front surface side and the wafer is divided along the planned dividing lines. The die bonding resin layer forming apparatus includes a liquid resin applying part including a chuck table that holds the wafer in such a manner that the back surface side is exposed and an applying unit that applies a liquid resin to the back surface side of the wafer held by the chuck table, a waiting part that holds the wafer to which the liquid resin has been applied by the liquid resin applying part and waits to dry the liquid resin applied to the wafer while enhancing flatness of the liquid resin, a curing part that gives an external stimulus to the liquid resin dried by the waiting part to cure the liquid resin and form the die bonding resin layer, and a conveying unit that conveys the wafer among the liquid resin applying part, the waiting part, and the curing part.

In the aspect of the present invention, the die bonding resin layer forming apparatus may further include a control unit that repeats application of the liquid resin at the liquid resin applying part and drying of the liquid resin at the waiting part and selects drying of the liquid resin by the waiting part or curing of the liquid resin by the curing part according to the number of times of the application of the liquid resin to the wafer.

Furthermore, in the aspect of the present invention, the liquid resin applying part may have a first liquid resin applying part and a second liquid resin applying part each including the chuck table and the applying unit, and the chuck table of the first liquid resin applying part and the chuck table of the second liquid resin applying part may be used also as the waiting part. Moreover, while the wafer after the liquid resin is applied by the applying unit of the first liquid resin applying part is held by the chuck table of the first liquid resin applying part and waiting is carried out to dry the liquid resin, the liquid resin may be applied to another wafer by the applying unit of the second liquid resin applying part.

The die bonding resin layer forming apparatus according to the aspect of the present invention includes the liquid resin applying part that applies the liquid resin to the wafer, the waiting part that dries the liquid resin applied to the wafer while enhancing the flatness of the liquid resin, and the curing part that cures the liquid resin dried by the waiting part and forms the die bonding resin layer.

Thus, the resin layer for die bonding with high flatness can be formed on the back surface side of the wafer by applying the liquid resin to the back surface side of the wafer by the liquid resin applying part and drying the liquid resin while enhancing the flatness of the liquid resin by the waiting part and thereafter curing the liquid resin by the curing part. As above, according to the one aspect of the present invention, a die bonding resin layer forming apparatus that can form the die bonding resin layer with high flatness on the wafer is obtained.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a plan view schematically depicting a configuration example of a die bonding resin layer forming apparatus;

FIG. 2 is a perspective view schematically depicting a configuration example of a wafer and so forth;

FIG. 3 is a partially sectional side view schematically depicting how a liquid-state resin is applied to the back surface side of the wafer;

FIG. 4A is a partially sectional side view schematically depicting how a liquid-state resin layer is dried while the flatness of the liquid-state resin layer is enhanced;

FIG. 4B is a diagram that enlarges part of FIG. 4A;

FIG. 5 is a partially sectional side view schematically depicting how the liquid-state resin layer is cured;

FIG. 6 is a perspective view schematically depicting a configuration example of the wafer and so forth according to a modification example;

FIG. 7A is a perspective view schematically depicting how the wafer is overlapped on a support plate;

FIG. 7B is a partially sectional side view schematically depicting how the wafer is overlapped on the support plate;

FIG. 8A is a perspective view schematically depicting the state in which the wafer is overlapped on the support plate;

FIG. 8B is a partially sectional side view schematically depicting the state in which the wafer is overlapped on the support plate; and

FIG. 9A, FIG. 9B, and FIG. 9C are partially sectional side views schematically depicting how the wafer is conveyed together with the support plate.

### DETAILED DESCRIPTION OF THE PREFERRED EMBODIMENT

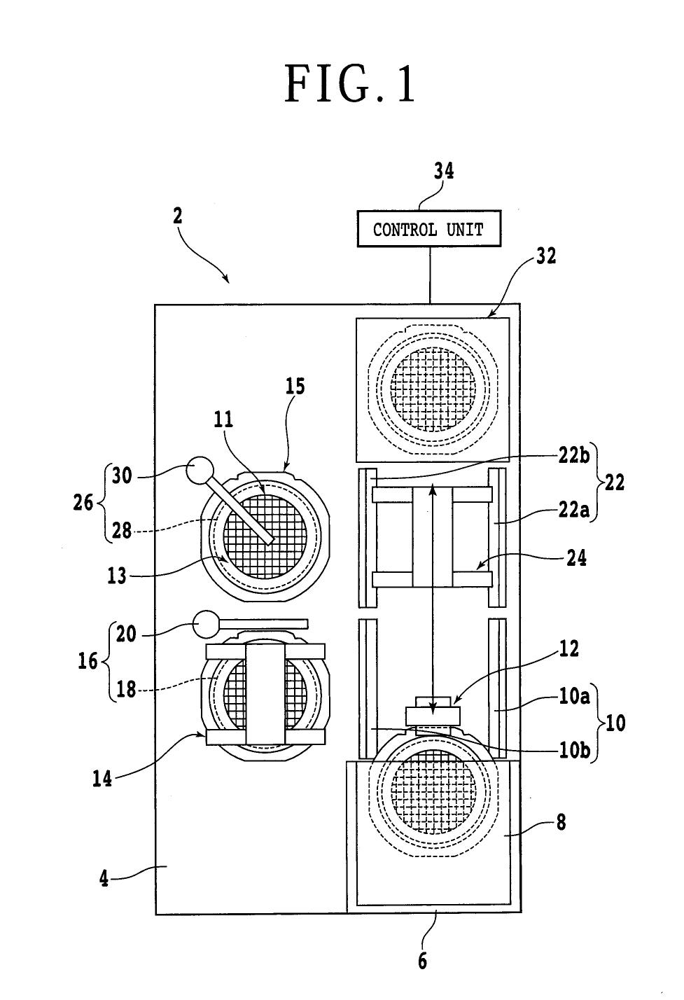

An embodiment according to one aspect of the present invention will be described with reference to the accompanying drawings. FIG. 1 is a plan view schematically depicting a configuration example of a die bonding resin layer forming apparatus 2 according to the present embodiment. In FIG. 1, part of constituent elements is depicted by a functional block.

As depicted in FIG. 1, the die bonding resin layer forming apparatus 2 includes a base 4 that supports the respective constituent elements. A cassette support pedestal 6 that moves up and down by an elevating mechanism (not depicted) is disposed at a corner part on the front side of the base 4. A cassette 8 that houses plural wafers 11 is placed on the upper surface of the cassette support pedestal 6.

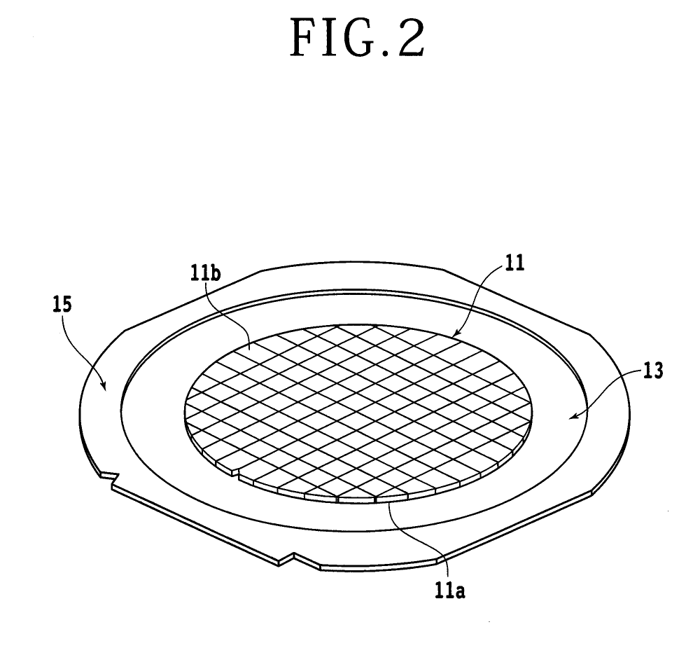

FIG. 2 is a perspective view schematically depicting a configuration example of a wafer 11 and so forth. The wafer 11 is formed into a circular disc shape by using a semiconductor material such as silicon for example. The side of a front surface 11a (in FIG. 2, lower surface) of the wafer 11 is segmented into plural regions by plural planned dividing lines (streets) that intersect each other and a device (not depicted) such as an integrated circuit (IC) is formed in each region.

To the side of the front surface 11a of the wafer 11, a protective member 13 having a larger diameter than this wafer 11 is stuck. As the protective member 13, an adhesive tape composed of a material such as a resin is used for example. The outer circumferential part of the protective member 13 is fixed to a ring-shaped frame 15 composed of stainless steel, aluminum, or the like. The wafer 11 is divided into plural device chips in advance along the above-described plural planned dividing lines and is housed in the cassette 8 in the state of being supported by the frame 15 with the intermediary of the protective member 13 (that is, in the state in which the side of a back surface 11b is exposed).

Although the circular-disc-shaped wafer 11 composed of a semiconductor material such as silicon is used in the present embodiment, there is no limit on the material, shape, structure, size, and so forth of the wafer 11. For example, it is also possible to use the wafer 11 composed of a material such as another semiconductor, ceramic, resin, or metal. Furthermore, there is no limit also on the kind, quantity, shape, structure, size, arrangement, and so forth of the devices.

As depicted in FIG. 1, on the rear side of the cassette support pedestal 6, a first guide mechanism 10 for guiding conveyance of the wafer 11 supported by the frame 15 is disposed. The first guide mechanism 10 includes a pair of guide rails 10a and 10b that move closer to and further away from each other. The respective guide rails 10a and 10b have a support surface substantially horizontal and a clamping surface substantially perpendicular to the support surface.

A first conveying unit 12 that grips the frame 15 and moves forward and rearward is disposed between the guide rail 10a and the guide rail 10b. By the first conveying unit 12, the frame 15 housed in the cassette 8 is gripped and drawn out onto the support surfaces of the guide rails 10a and 10b. When the frame 15 is drawn out from the cassette 8, the height of the cassette 8 is adjusted by the cassette support pedestal 6 and the guide rails 10a and 10b are made to get away from each other in advance.

After the frame 15 is drawn out to the guide rails 10a and 10b, these guide rails 10a and 10b are brought closer to each other. As a result, the frame 15 is clamped by the clamping surfaces of the guide rails 10a and 10b and the wafer 11 supported by the frame 15 is adjusted to a predetermined position.

A second conveying unit 14 that holds and conveys the frame 15 supporting the wafer 11 is disposed above a region including the first guide mechanism 10. Furthermore, on a lateral side of the first guide mechanism 10, a first applying-drying unit (liquid resin applying part) 16 that applies a liquid-state resin (liquid resin) that cures to become an adhesive for die bonding by being given a stimulus such as light or heat (external stimulus) to the side of the back surface 11b of the wafer 11 and dries the liquid-state resin is disposed.

The first applying-drying unit 16 includes a chuck table (waiting part) 18 that sucks and holds the wafer 11. For example, the chuck table 18 is joined to a rotational drive source (not depicted) such as a motor and rotates around a rotation axis substantially parallel to the vertical direction. The upper surface of the chuck table 18 serves as a holding surface for sucking and holding the wafer 11. The holding surface is connected to a suction source such as an ejector (not depicted) via a suction path (not depicted) and so forth made inside the chuck table 18.

A nozzle unit (applying unit) 20 that turns the liquid-state resin to a mist state and injects the resin is disposed above the chuck table 18. For example, the wafer 11 carried out from the first guide mechanism 10 by the second conveying unit 14 is placed on the chuck table 18 in such a manner that the side of the back surface 11b is exposed upward.

Thereafter, a negative pressure of the suction source is made to act on the holding surface of the chuck table 18. Thereby, the wafer 11 is sucked and held by the chuck table 18. Then, by rotating the chuck table 18 and injecting the liquid-state resin downward from the nozzle unit 20, the liquid-state resin is applied to the side of the back surface 11b of the wafer 11. The chuck table 18 does not necessarily have to be rotated while the liquid-state resin is injected from the nozzle unit 20. That is, the liquid-state resin can be applied without rotating the chuck table 18.

After the liquid-state resin is applied to the side of the back surface 11b of the wafer 11, for example, the chuck table 18 waits in the state of holding this wafer 11. Thereby, the liquid-state resin applied to the side of the back surface 11b of the wafer 11 is planarized by the action of gravity and so forth. Furthermore, the liquid-state resin gradually dries and it becomes hard for the shape thereof to change even when the liquid-state resin is further applied in an overlapped manner.

As above, the chuck table 18 of the first applying-drying unit 16 has a function of drying the liquid-state resin applied to the wafer 11 while enhancing the flatness of the liquid-state resin by holding the wafer 11 and waiting. The time of the waiting is set according to conditions such as the viscosity, material, and thickness of application (amount of application) of the liquid-state resin. After the above-described processing, the wafer 11 is conveyed to the first guide mechanism 10 by the second conveying unit 14 for example.

A second guide mechanism 22 for guiding conveyance of the wafer 11 supported by the frame 15 is disposed on the rear side of the first guide mechanism 10. The basic structure of the second guide mechanism 22 is the same as the first guide mechanism 10. Specifically, the second guide mechanism 22 includes a pair of guide rails 22a and 22b that move closer to and further away from each other. The respective guide rails 22a and 22b have a support surface substantially horizontal and a clamping surface substantially perpendicular to the support surface.

A third conveying unit 24 that holds and conveys the frame 15 supporting the wafer 11 is disposed above a region including the second guide mechanism 22. Furthermore, on a lateral side of the second guide mechanism 22 and on the rear side of the first applying-drying unit 16, a second applying-drying unit (liquid resin applying part) 26 that applies the liquid-state resin (liquid resin) that cures to become an adhesive for die bonding by being given a stimulus such as light or heat (external stimulus) to the side of the back surface 11b of the wafer 11 and dries the liquid-state resin is disposed.

The basic structure of the second applying-drying unit 26 is the same as the first applying-drying unit 16. Specifically, the second applying-drying unit 26 includes a chuck table (waiting part) 28 that sucks and holds the wafer 11. For example, the chuck table 28 is joined to a rotational drive source (not depicted) such as a motor and rotates around a rotation axis substantially parallel to the vertical direction.

The upper surface of the chuck table 28 serves as a holding surface for sucking and holding the wafer 11. The holding surface is connected to a suction source such as an ejector (not depicted) via a suction path (not depicted) and so forth made inside the chuck table 28. A nozzle unit (applying unit) 30 that turns the liquid-state resin to a mist state and injects the resin is disposed above the chuck table 28.

For example, the frame 15 supporting the wafer 11 is drawn out from the guide rails 10a and 10b onto the support surfaces of the guide rails 22a and 22b by the above-described first conveying unit 12. When the frame 15 is drawn out onto the support surfaces of the guide rails 22a and 22b, the guide rails 22a and 22b are made to get away from each other in advance.

After the frame 15 is drawn out to the guide rails 22a and 22b, these guide rails 22a and 22b are brought closer to each other. As a result, the frame 15 is clamped by the clamping surfaces of the guide rails 22a and 22b and the wafer 11 supported by the frame 15 is adjusted to a predetermined position.

For example, the wafer 11 carried out from the second guide mechanism 22 by the third conveying unit 24 is placed on the chuck table 28 in such a manner that the side of the back surface 11b is exposed upward. Thereafter, a negative pressure of the suction source is made to act on the holding surface of the chuck table 28. Thereby, the wafer 11 is sucked and held by the chuck table 28.

Then, by rotating the chuck table 28 and injecting the liquid-state resin downward from the nozzle unit 30, the liquid-state resin is applied to the side of the back surface 11b of the wafer 11. The chuck table 28 does not necessarily have to be rotated while the liquid-state resin is injected from the nozzle unit 30.

After the liquid-state resin is applied to the side of the back surface 11b of the wafer 11, for example, the chuck table 28 waits in the state of holding this wafer 11. Thereby, the liquid-state resin applied to the side of the back surface 11b of the wafer 11 is planarized by the action of gravity and so forth. Furthermore, the liquid-state resin gradually dries and it becomes hard for the shape thereof to change even when the liquid-state resin is further applied in an overlapped manner.

As above, the chuck table 28 of the second applying-drying unit 26 also has a function of drying the liquid-state resin applied to the wafer 11 while enhancing the flatness of the liquid-state resin by holding the wafer 11 and waiting. After the above-described processing, the wafer 11 is conveyed to the second guide mechanism 22 by the third conveying unit 24 for example.

On the further rear side of the second guide mechanism 22, a curing unit (curing part) 32 that gives a stimulus such as light or heat (external stimulus) to the liquid-state resin that has been applied to the side of the back surface 11b of the wafer 11 and been dried to a certain extent and cures the liquid-state resin is disposed. In the present embodiment, the curing unit 32 that carries out irradiation with an ultraviolet ray as the stimulus for curing the liquid-state resin is used. However, the concrete function, structure, and so forth of the curing unit 32 can be changed according to the material and so forth of the liquid-state resin.

After the frame 15 supporting the wafer 11 is conveyed to the second guide mechanism 22, this frame 15 is slid by the first conveying unit 12 to be carried in to the curing unit 32. Then, the liquid-state resin applied to the side of the back surface 11b of the wafer 11 is irradiated with an ultraviolet ray by the curing unit 32. As a result, the liquid-state resin cures and a resin layer (die bonding resin layer) that functions as an adhesive for die bonding is formed.

A control unit 34 is connected to the cassette support pedestal 6, the first guide mechanism 10, the first conveying unit 12, the second conveying unit 14, the first applying-drying unit 16, the second guide mechanism 22, the third conveying unit 24, the second applying-drying unit 26, the curing unit 32, and so forth. The control unit 34 controls operation of the respective constituent elements so that the resin layer for die bonding with high flatness can be formed on the side of the back surface 11b of the wafer 11.

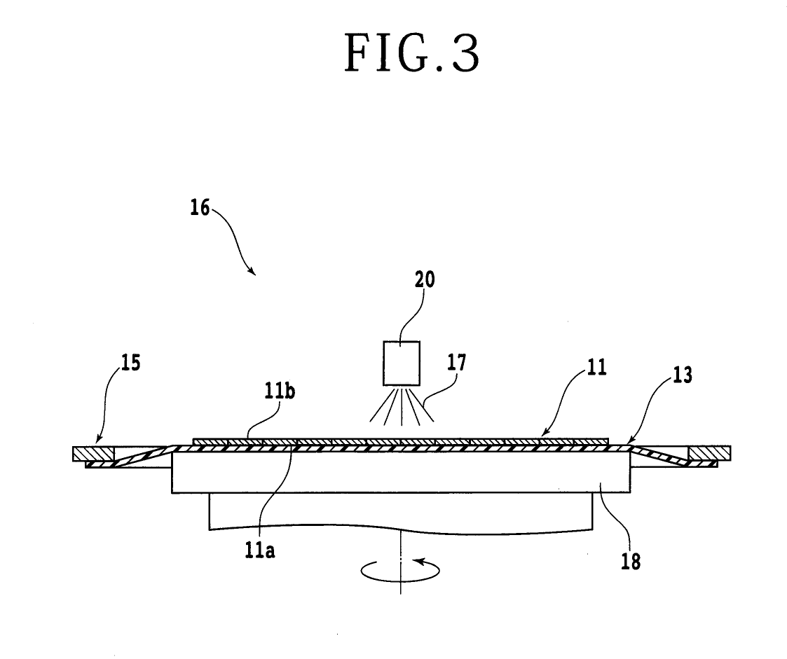

Next, an example of a die bonding resin layer forming method carried out by using the above-described die bonding resin layer forming apparatus 2 will be described. In the die bonding resin layer forming method according to the present embodiment, first, a first applying step of applying a liquid-state resin to the side of the back surface 11b of the wafer 11 is carried out. FIG. 3 is a partially sectional side view schematically depicting how a liquid-state resin 17 is applied to the side of the back surface 11b of the wafer 11 in the first applying step.

In the first applying step, for example, the wafer 11 supported by the first guide mechanism 10 is conveyed by the second conveying unit 14 to be placed on the chuck table 18 of the first applying-drying unit 16. At this time, the protective member 13 stuck to the side of the front surface 11a of the wafer 11 is brought into contact with the holding surface of the chuck table 18 so that the side of the back surface 11b of the wafer 11 may be exposed upward. Next, a negative pressure of the suction source is made to act on the holding surface of the chuck table 18. Thereby, the wafer 11 is sucked and held by the chuck table 18 with the intermediary of the protective member 13.

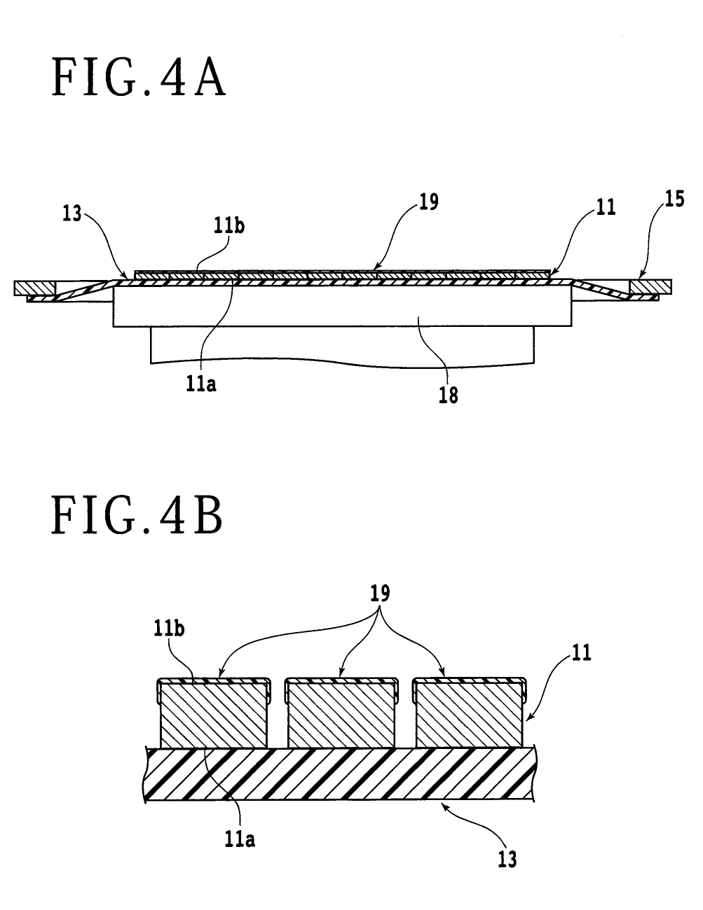

After the wafer 11 is sucked and held by the chuck table 18, this chuck table 18 is rotated and the liquid-state resin 17 is injected downward from the nozzle unit 20. As a result, the liquid-state resin 17 is applied to the side of the back surface 11b of the wafer 11 and a liquid-state resin layer 19 (see FIG. 4A and so forth) made of the liquid-state resin 17 is formed. However, it is possible to apply the liquid-state resin 17 and form the liquid-state resin layer 19 without rotating the chuck table 18 as described above.

In the present embodiment, a resin of an ultraviolet curing type that cures by irradiation with an ultraviolet ray is used as the liquid-state resin 17. However, it is also possible to use a resin that cures by being given a stimulus such as light with a wavelength other than that of the ultraviolet ray or heat (external stimulus) as the liquid-state resin 17. Furthermore, although the amount of application of the liquid-state resin 17 is not particularly limited, the amount of application of the liquid-state resin 17 is adjusted to cause the thickness of the liquid-state resin layer 19 to become about 5 μm to 7 μm in the present embodiment.

After the first applying step, a first waiting step of drying the liquid-state resin layer 19 formed on the wafer 11 while enhancing the flatness of this liquid-state resin layer 19 is carried out. FIG. 4A is a partially sectional side view schematically depicting how the liquid-state resin layer 19 is dried while the flatness of the liquid-state resin layer 19 is enhanced in the first waiting step. FIG. 4B is an enlarged view that enlarges part of FIG. 4A.

The viscosity of the liquid-state resin 17 applied on the side of the back surface 11b of the wafer 11 is comparatively high. Thus, the possibility that the surface of the liquid-state resin layer 19 has recess and projection is high immediately after the liquid-state resin 17 is applied and the liquid-state resin layer 19 is formed. If the liquid-state resin layer 19 is cured in the state in which the surface has recess and projection, a sufficiently-flat resin layer is not obtained. Furthermore, if the liquid-state resin 17 is further applied on this liquid-state resin layer 19 in the state in which the surface has recess and projection, larger recess and projection are formed in the surface of the liquid-state resin 17 newly applied.

Thus, in the present embodiment, after the liquid-state resin 17 is applied to the side of the back surface 11b of the wafer 11 and the liquid-state resin layer 19 is formed, the chuck table 18 in the state of holding this wafer 11 is made to wait. The time of the waiting is set according to conditions such as the viscosity, material, and thickness of application (amount of application) of the liquid-state resin 17, and is set to preferably one minute or longer and more preferably three minutes or longer. Thereby, the liquid-state resin layer 19 formed on the side of the back surface 11b of the wafer 11 is planarized by the action of gravity and so forth.

Furthermore, the liquid-state resin layer 19 gradually dries and it becomes hard for the shape thereof to change even when the liquid-state resin 17 is further applied in an overlapped manner. After the waiting for the predetermined time ends, the wafer 11 is released from the suction and holding by the chuck table 18 and conveyed to the first guide mechanism 10 by the second conveying unit 14.

After the first waiting step, a second applying step of further applying the liquid-state resin 17 to the surface of the dried liquid-state resin layer 19 is carried out. In the second applying step, the same processing as the above-described first applying step is carried out by the second applying-drying unit 26.

Specifically, for example, the wafer 11 supported by the first guide mechanism 10 is conveyed to the second guide mechanism 22 by the first conveying unit 12. Furthermore, the wafer 11 supported by the second guide mechanism 22 is carried out by the third conveying unit 24 and is placed on the chuck table 28 of the second applying-drying unit 26.

At this time, the protective member 13 stuck to the side of the front surface 11a of the wafer 11 is brought into contact with the holding surface of the chuck table 28 so that the liquid-state resin layer 19 formed on the side of the back surface 11b of the wafer 11 may be exposed upward. Next, a negative pressure of the suction source is made to act on the holding surface of the chuck table 28. Thereby, the wafer 11 is sucked and held by the chuck table 28 with the intermediary of the protective member 13.

After the wafer 11 is sucked and held by the chuck table 28, this chuck table 28 is rotated and the liquid-state resin 17 is injected downward from the nozzle unit 30. As a result, the liquid-state resin 17 is further applied to the side of the back surface 11b of the wafer 11 and another liquid-state resin layer 19 is formed on the liquid-state resin layer 19 already formed.

In the above-described first waiting step, the liquid-state resin layer 19 formed in the first applying step has been dried to a certain extent. Therefore, the liquid-state resin layer 19 formed in the second applying step and the liquid-state resin layer 19 formed in the first applying step hardly mix with each other. Thus, the lowering of the flatness due to the mixing of the liquid-state resin layer 19 formed in the second applying step and the liquid-state resin layer 19 formed in the first applying step with each other is also not caused.

After the second applying step, a second waiting step of drying the liquid-state resin layer 19 formed on the wafer 11 while enhancing the flatness of this liquid-state resin layer 19 is carried out. In the second waiting step, the same processing as the above-described first waiting step is carried out by the chuck table 28 of the second applying-drying unit 26.

Specifically, after the liquid-state resin 17 is applied to the side of the back surface 11b of the wafer 11 and the other liquid-state resin layer 19 is formed in the second applying step, the chuck table 28 is made to wait in the state of holding the wafer 11. Thereby, the new liquid-state resin layer 19 formed on the side of the back surface 11b of the wafer 11 in the second applying step is planarized by the action of gravity and so forth.

Furthermore, the liquid-state resin layer 19 formed in the second applying step gradually dries and it becomes hard for the shape thereof to change even when the liquid-state resin 17 is further applied in an overlapped manner. After the waiting for the predetermined time ends, the wafer 11 is released from the suction and holding by the chuck table 28 and conveyed to the second guide mechanism 22 by the third conveying unit 24.

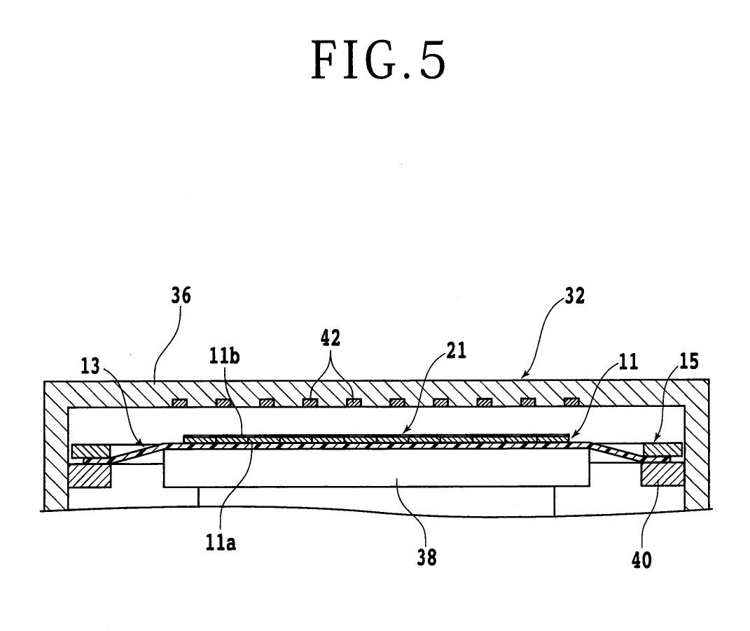

After the second waiting step, a curing step of irradiating the liquid-state resin layer 19 formed on the side of the back surface 11b of the wafer 11 with an ultraviolet ray and curing this liquid-state resin layer 19 is carried out. FIG. 5 is a partially sectional side view schematically depicting how the liquid-state resin layer 19 is cured in the curing step.

As depicted in FIG. 5, the curing unit 32 includes a casing 36 having a space for processing (processing chamber) inside for example. In the space of the casing 36, a chuck table 38 that holds the wafer 11 and a support rail 40 that supports the frame 15 are disposed. Plural light sources 42 that radiate the ultraviolet ray downward are disposed above the chuck table 38.

In the curing step, the frame 15 supported by the second guide mechanism 22 is slid by the first conveying unit 12 to be carried in to the curing unit 32 for example. Specifically, the protective member 13 stuck to the side of the front surface 11a of the wafer 11 is brought into contact with the upper surface of the chuck table 38 so that the side of the back surface 11b of the wafer 11 may be exposed upward. Furthermore, the support rail 40 is made to support the frame 15.

Next, the ultraviolet ray is radiated from the plural light sources 42 toward the side of the back surface 11b of the wafer 11. Thereby, the liquid-state resin layer 19 made on the side of the back surface 11b of the wafer 11 cures by the ultraviolet ray and a resin layer (die bonding resin layer) 21 that functions as an adhesive for die bonding is formed. After the liquid-state resin layer 19 is cured to form the resin layer 21, for example, the frame 15 supporting this wafer 11 may be conveyed by the first conveying unit 12 and be housed in the cassette 8.

As described above, the die bonding resin layer forming apparatus 2 according to the present embodiment includes the first applying-drying unit (liquid resin applying part) 16 and the second applying-drying unit (liquid resin applying part) 26 that apply the liquid-state resin (liquid resin) 17 to the wafer 11, the chuck table (waiting part) 18 and the chuck table (waiting part) 28 that dry the liquid-state resin layer 19 formed on the wafer 11 while enhancing the flatness of the liquid-state resin layer 19, and the curing unit (curing part) 32 that cures the liquid-state resin layer 19 dried by the chuck table (waiting part) 18 or the chuck table (waiting part) 28 and forms the resin layer (die bonding resin layer) 21 that functions as an adhesive for die bonding.

Thus, the resin layer 21 for die bonding with high flatness can be formed on the side of the back surface 11b of the wafer 11 by applying the liquid-state resin 17 to the side of the back surface 11b of the wafer 11 by the first applying-drying unit 16 or the second applying-drying unit 26 and drying the liquid-state resin layer 19 while enhancing the flatness of the liquid-state resin layer 19 by the chuck table 18 or the chuck table 28 and thereafter curing the liquid-state resin layer 19 by the curing unit 32.

The present invention is not limited to the description of the above-described embodiment and so forth and can be carried out with various changes. For example, in the above-described embodiment, the liquid-state resin layer 19 formed on the wafer 11 is dried while the flatness of this liquid-state resin layer 19 is enhanced by using the chuck table 18 of the first applying-drying unit 16 and the chuck table 28 of the second applying-drying unit 26. However, it is also possible to dispose another table or the like that functions as a waiting part on which the wafer 11 is made to wait in the die bonding resin layer forming apparatus 2.

Furthermore, in the die bonding resin layer forming method of the above-described embodiment, the first applying-drying unit 16 is not used when the second applying step and the second waiting step are carried out. In the period during which one of the first applying-drying unit 16 and the second applying-drying unit 26 is not used as above, the liquid-state resin 17 may be applied to the side of the back surface 11b of another wafer 11 by using this one of the first applying-drying unit 16 and the second applying-drying unit 26.

Specifically, while the wafer 11 after the liquid-state resin 17 is applied by the nozzle unit 30 of the second applying-drying unit 26 is held by the chuck table 28 of the second applying-drying unit 26 and waiting is carried out to dry the liquid-state resin layer 19, the liquid-state resin 17 can be applied to another wafer 11 by the nozzle unit (applying unit) 20 of the first applying-drying unit 16.

Similarly, while the wafer 11 after the liquid-state resin 17 is applied by the nozzle unit 20 of the first applying-drying unit 16 is held by the chuck table 18 of the first applying-drying unit 16 and waiting is carried out to dry the liquid-state resin layer 19, the liquid-state resin 17 can be applied to another wafer 11 by the nozzle unit 30 of the second applying-drying unit 26.

Furthermore, in the die bonding resin layer forming method of the above-described embodiment, the liquid-state resin 17 is applied by the first applying-drying unit 16 one time and applied by the second applying-drying unit 26 one time and two layers of the liquid-state resin layer 19 are formed. However, the number of times of the application of the liquid-state resin 17 is not particularly limited. For example, the number of times of the application of the liquid-state resin 17 may be one or may be three or more.

Moreover, in the die bonding resin layer forming method of the above-described embodiment, after the liquid-state resin layer 19 is formed by using the first applying-drying unit 16, another liquid-state resin layer 19 is formed by using the second applying-drying unit 26. However, it is also possible to form plural liquid-state resin layers 19 by using only one of the first applying-drying unit 16 and the second applying-drying unit 26. In this case, the liquid-state resin layer 19 may be formed on another wafer 11 by using the other of the first applying-drying unit 16 and the second applying-drying unit 26.

In addition, the last waiting step (in the above-described embodiment, the second waiting step) carried out immediately before the curing step may be omitted. This is because the liquid-state resin 17 is not applied to the surface of the liquid-state resin layer 19 formed last and the adverse effect on the flatness of the resin layer 21 does not become so large even when the last waiting step is omitted.

In this case, according to the number of times of application of the liquid-state resin 17 to the wafer 11, the control unit 34 selects drying the liquid-state resin layer 19 by the chuck table 18 or the chuck table 28, or curing the liquid-state resin layer 19 by the curing unit 32.

Moreover, in the above-described embodiment, two sets of applying-drying unit (the first applying-drying unit 16 and the second applying-drying unit 26) are disposed in the die bonding resin layer forming apparatus 2. However, the number of sets of applying-drying unit (liquid resin applying part) disposed in the die bonding resin layer forming apparatus of the present invention may be one or may be three or more.

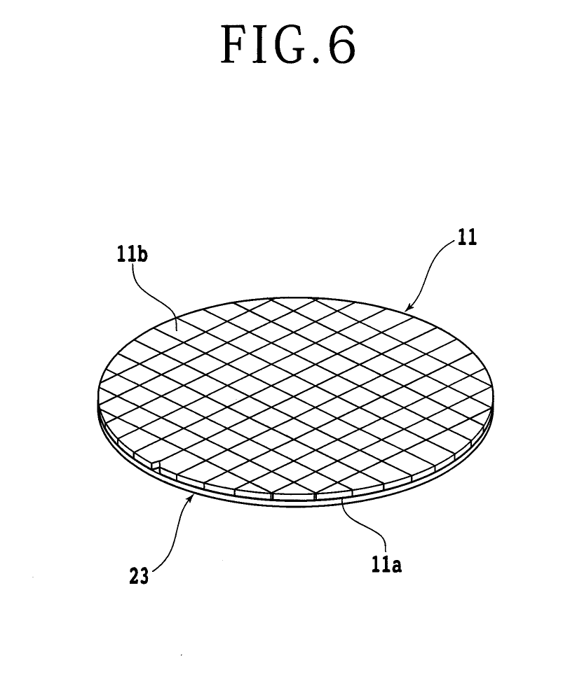

Furthermore, in the above-described embodiment, the protective member 13 with a larger diameter than the wafer 11 is stuck to the side of the front surface 11a of the wafer 11. However, it is also possible to stick a protective member with a diameter equivalent to that of the wafer 11 to the side of the front surface 11a of the wafer 11. FIG. 6 is a perspective view schematically depicting a configuration example of the wafer 11 and so forth according to a modification example.

As depicted in FIG. 6, in this modification example, a protective member 23 with a diameter equivalent to that of the wafer 11 is stuck to the side of the front surface 11a of the wafer 11. In this modification example, besides an adhesive tape composed of a material such as a resin, a substrate or the like composed of an arbitrary material can be used as the protective member 23. The wafer 11 may be the same as the above-described embodiment.

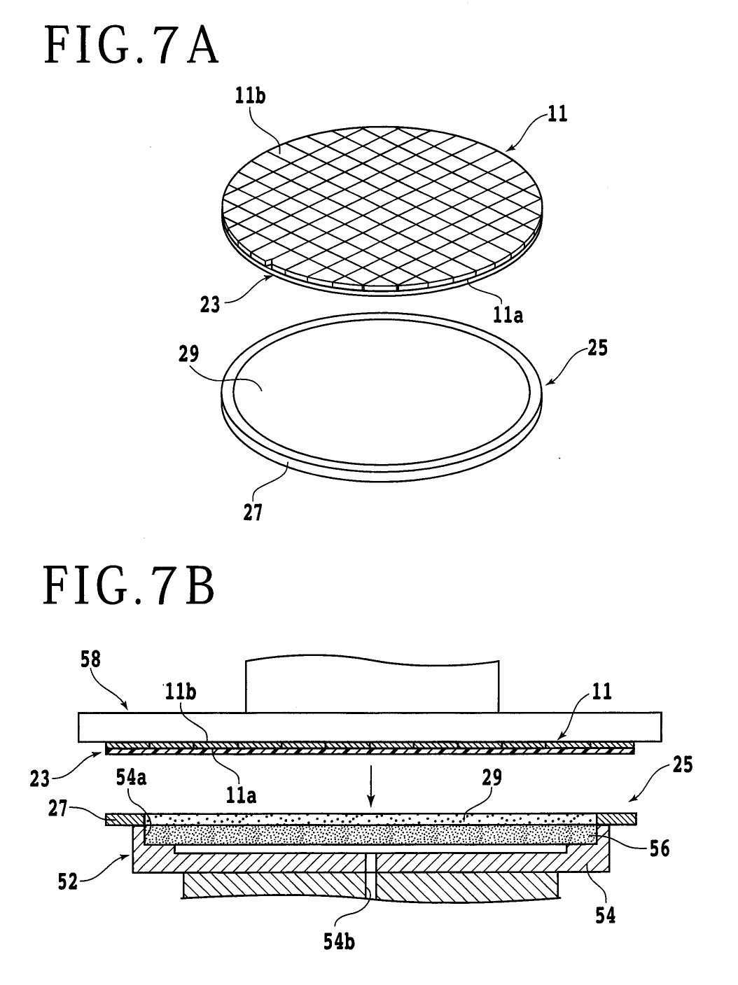

Incidentally, the wafer 11 can not be supported by the frame 15 if the protective member 23 with a diameter equivalent to that of the wafer 11 is stuck to the side of the front surface 11a of the wafer 11 as depicted in FIG. 6. In this case, it is preferable to overlap the wafer 11 on a support plate with a diameter equivalent to that of the wafer 11 and support the wafer 11 by this support plate. FIG. 7A is a perspective view schematically depicting how the wafer 11 is overlapped on a support plate 25. FIG. 7B is a partially sectional side view schematically depicting how the wafer 11 is overlapped on the support plate 25.

As depicted in FIG. 7A, the support plate 25 includes a ring-shaped frame part 27 composed of stainless steel, aluminum, or the like and an air-passing part 29 disposed inside the frame part 27. The outer diameter of the frame part 27 is equivalent to the diameter of the wafer 11 and the protective member 23. The air-passing part 29 is composed of a porous material for example and allows passing of air therethrough. The opening itself of the frame part 27 may be employed as the air-passing part 29 without using the porous material or the like.

When the wafer 11 is overlapped on the support plate 25, as depicted in FIG. 7B, first the support plate 25 is placed on the upper surface of a chuck table 52. The chuck table 52 includes a circular-disc-shaped frame body 54. A recessed part 54a with a circular shape in plan view is made in the upper surface of the frame body 54. A holding plate 56 that is composed of a porous material and has a circular disc shape is disposed in the recessed part 54a.

The holding plate 56 is connected to a suction source such as an ejector (not depicted) via a suction path 54b and so forth made inside the frame body 54. Thus, a negative pressure of the suction source can be made to act on the upper surface of the holding plate 56. The diameter of the recessed part 54a and the holding plate 56 is equivalent to the inner diameter of the frame part 27 and the diameter of the air-passing part 29.

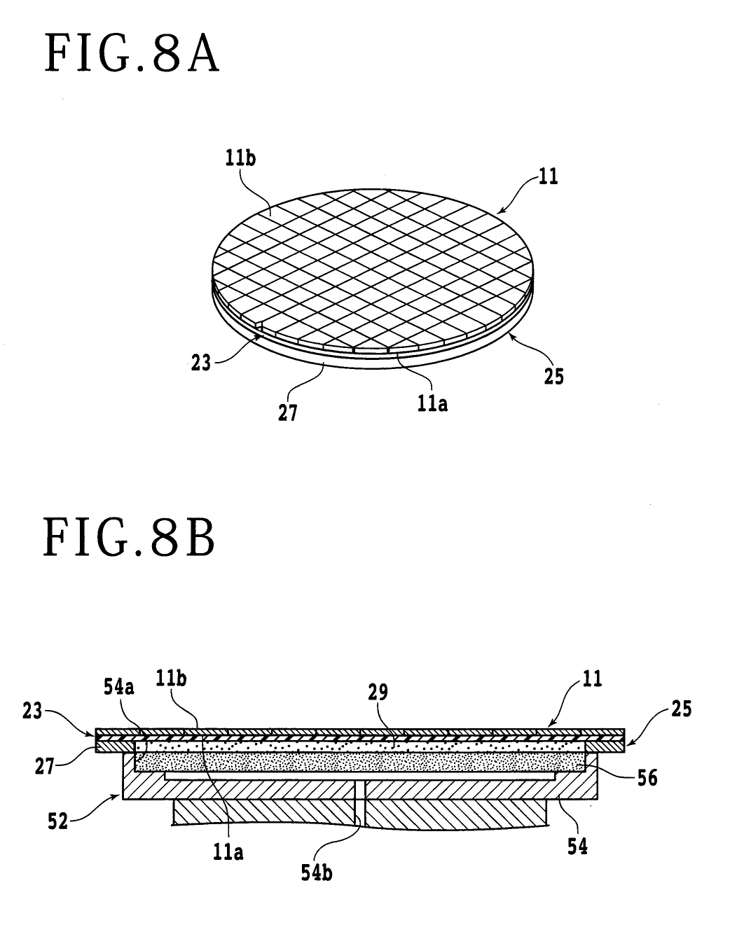

After the support plate 25 is placed on the upper surface of the chuck table 52, the side of the back surface 11b of the wafer 11 is sucked and held by a conveying pad 58 or the like and the protective member 23 stuck to the side of the front surface 11a is brought into contact with the upper surface of the support plate 25. FIG. 8A is a perspective view schematically depicting the state in which the wafer 11 is overlapped on the support plate 25. FIG. 8B is a partially sectional side view schematically depicting the state in which the wafer 11 is overlapped on the support plate 25.

As depicted in FIG. 8A and FIG. 8B, when the negative pressure of the suction source is made to act on the upper surface of the holding plate 56 in the state in which the wafer 11 is overlapped on the support plate 25, the wafer 11 is sucked and held by the chuck table 52 with the intermediary of the protective member 23 and the support plate 25.

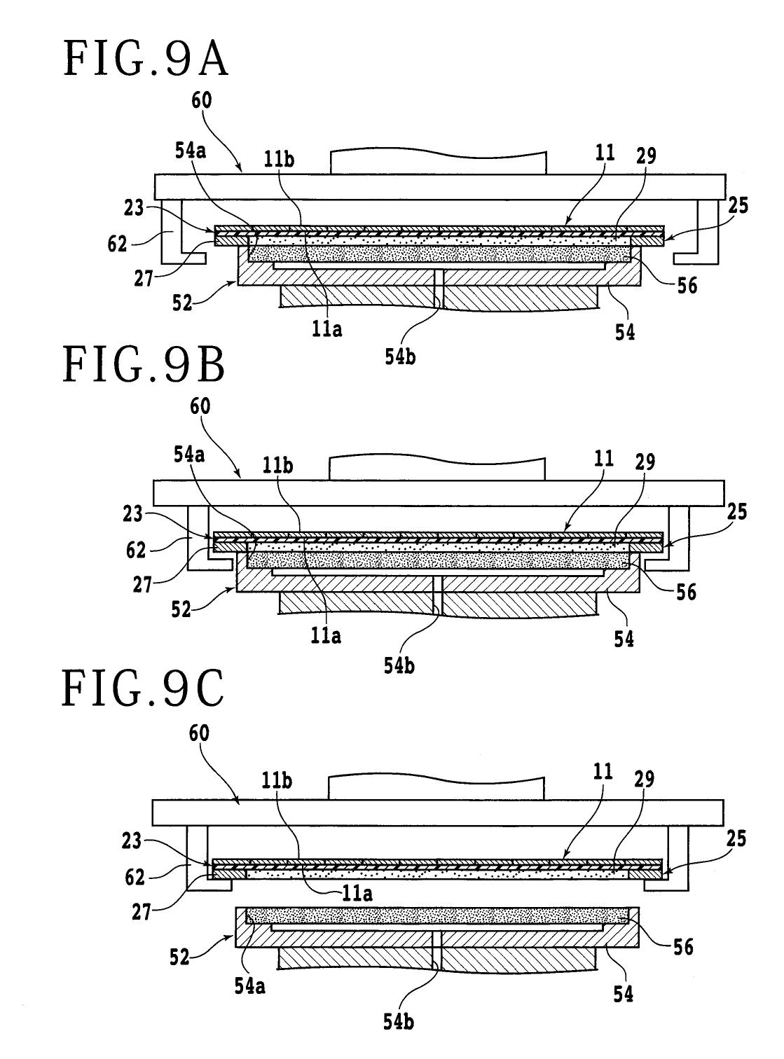

FIG. 9A, FIG. 9B, and FIG. 9C are partially sectional side views schematically depicting how the wafer 11 is conveyed together with the support plate 25. As depicted in FIG. 9A, FIG. 9B, and FIG. 9C, when the wafer 11 is conveyed together with the support plate 25, a conveying hand 60 with a structure that can hold the lower surface side of the support plate 25 is used. The conveying hand 60 has plural claws 62 with a shape with which the support plate 25 can be held from the lower surface side. Each claw 62 moves along the radial direction of the support plate 25.

When the wafer 11 is conveyed together with the support plate 25 by the conveying hand 60, as depicted in FIG. 9A, first the conveying hand 60 is moved to the upper side of the wafer 11 and the support plate 25, and each claw 62 is positioned outside the wafer 11 and the support plate 25. Thereafter, the conveying hand 60 is lowered and the tip part of each claw 62 is moved to the lower side relative to the support plate 25.

Next, as depicted in FIG. 9B, each claw 62 is moved inward along the radial direction of the support plate 25 and the tip part of each claw 62 is overlapped with the support plate 25 in plan view. Then, the conveying hand 60 is raised as depicted in FIG. 9C. Thereby, the support plate 25 can be held by the plural claws 62 and be conveyed together with the wafer 11.

Besides, structures, methods, and so forth according to the above-described embodiment and modification example can be carried out with appropriate changes without departing from the range of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A die bonding resin layer forming apparatus that forms a die bonding resin layer on a back surface side of a wafer on which devices are formed in a plurality of regions on a front surface side marked out by a plurality of planned dividing lines, a protective member being stuck to the front surface side, the wafer being divided along the planned dividing lines, the die bonding resin layer forming apparatus comprising:
a liquid resin applying part including a chuck table that holds the wafer in such a manner that the back surface side is exposed and an applying unit that applies a liquid resin to the back surface side of the wafer held by the chuck table;
a waiting part that holds the wafer to which the liquid resin has been applied by the liquid resin applying part and waits to dry the liquid resin applied to the wafer while enhancing flatness of the liquid resin;
a curing part that gives an external stimulus to the liquid resin dried by the waiting part to cure the liquid resin and form the die bonding resin layer; and
a conveying unit that conveys the wafer among the liquid resin applying part, the waiting part, and the curing part.

2. The die bonding resin layer forming apparatus according to claim 1, further comprising:
a control unit that repeats application of the liquid resin at the liquid resin applying part and drying of the liquid resin at the waiting part and selects drying of the liquid resin by the waiting part or curing of the liquid resin by the curing part according to the number of times of the application of the liquid resin to the wafer.

3. The die bonding resin layer forming apparatus according to claim 1, wherein
the liquid resin applying part has a first liquid resin applying part and a second liquid resin applying part each including the chuck table and the applying unit,
the chuck table of the first liquid resin applying part and the chuck table of the second liquid resin applying part are used also as the waiting part, and
while the wafer after the liquid resin is applied by the applying unit of the first liquid resin applying part is held by the chuck table of the first liquid resin applying part and waiting is carried out to dry the liquid resin, the liquid resin is applied to another wafer by the applying unit of the second liquid resin applying part.

4. The die bonding resin layer forming apparatus according to claim 2, wherein
the liquid resin applying part has a first liquid resin applying part and a second liquid resin applying part each including the chuck table and the applying unit,
the chuck table of the first liquid resin applying part and the chuck table of the second liquid resin applying part are used also as the waiting part, and
while the wafer after the liquid resin is applied by the applying unit of the first liquid resin applying part is held by the chuck table of the first liquid resin applying part and waiting is carried out to dry the liquid resin, the liquid resin is applied to another wafer by the applying unit of the second liquid resin applying part.
